(19) United States
(12) Patent Application Publication
(10) Pub. No.: US 2011/0210356 A1
(43) Pub. Date: Sep. 1, 2011

(54) SEMICONDUCTOR PACKAGE AND FABRICATION METHOD THEREOF

(75) Inventor: CHIH-MING CHEN, Hukou (TW)

(73) Assignee: ADVANCED OPTOELECTRONIC TECHNOLOGY, INC., Hsinchu Hsien (TW)

(21) Appl. No.: 12/978,427

(22) Filed: Dec. 24, 2010

(30) Foreign Application Priority Data
Feb. 26, 2010 (TW) 99105635

(51) Int. Cl. H01L 33/60; H01L 33/48

(52) U.S. Cl. 257/98; 438/27; 257/E33.056; 257/E33.072; 257/E33.059

(57) ABSTRACT

A light emitting element package includes a substrate, a reflection layer, at least one light emitting element, at least two conductive layers, a plurality of metal pins and an encapsulation layer. The reflection layer is formed on the substrate. The at least one light emitting element is mounted on the reflection layer on the substrate. The at least two conductive layers are electrically coupled to the at least one light emitting element. The metal pins electrically couple to the at least two conductive layers. The encapsulation layer is mounted on the substrate for encapsulating the at least one light emitting element.

### BACKGROUND

1. Technical Field

The disclosure relates generally to semiconductor packages, and more particularly to a light emitting element package and fabrication method for the package.

2. Description of the Related Art

Normally, heat generated by a LED chip is dissipated by electrodes connected thereto. The dissipation efficiency of the LED chip is not effective.

Further, when a ceramic substrate bearing a semiconductor package of the LED chip is fired, the surface of the ceramic substrate is often not smooth. The light from a light emitting element thereon will be scattered or refracted by the rough surface, and total luminance of the light emitting element package reduced.

Therefore, there is a need for improvement in the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout two views.

FIG. 1 is a flowchart of a fabrication method for a light emitting element package in accordance with a first embodiment of the disclosure.

FIGS. 2-7 and 9-10 are schematic views of a fabrication method for a light emitting element package in accordance with a first embodiment of the disclosure.

FIG. 8 is a top view of the light emitting element package in FIG. 7.

FIG. 11 is a top view of a light emitting element package with two light emitting elements in accordance with a second embodiment of the disclosure.

FIG. 12 is a cross-section taken along line B-B′ of the light emitting element in FIG. 11.

### DETAILED DESCRIPTION

The disclosure is illustrated by way of example and not by way of limitation in the figures of the accompanying drawings. It should be noted that references to “an” or “one” embodiment in this disclosure are not necessarily to the same embodiment, and such references mean at least one.

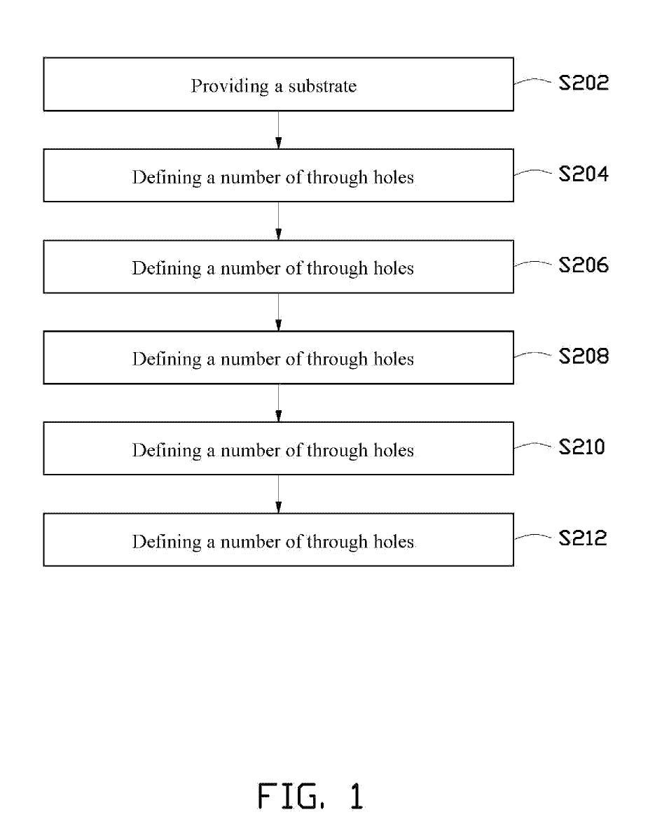

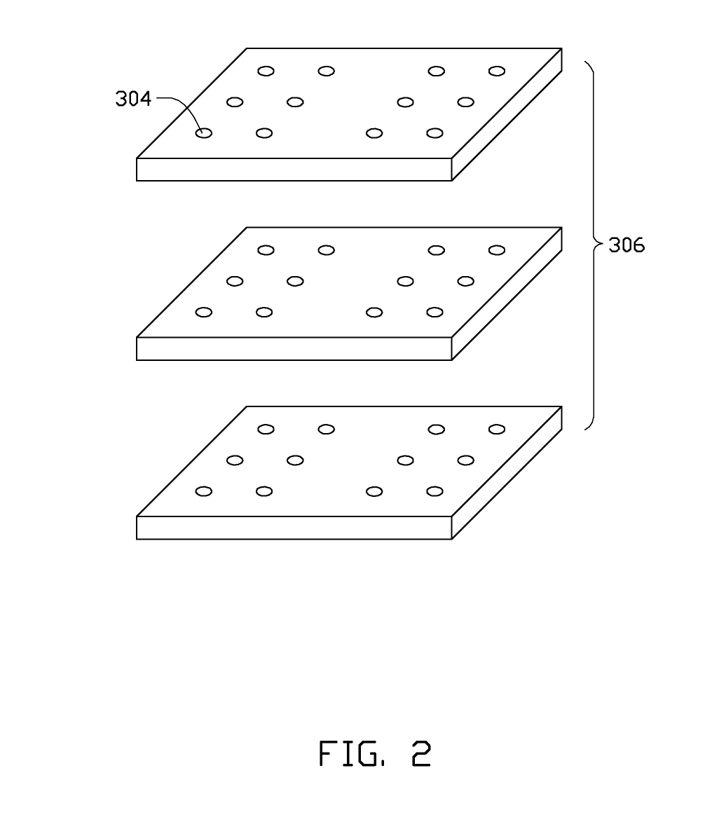

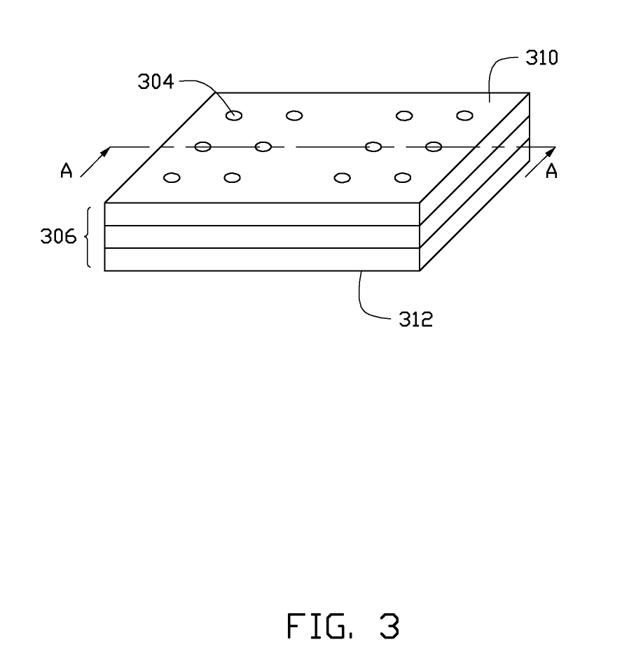

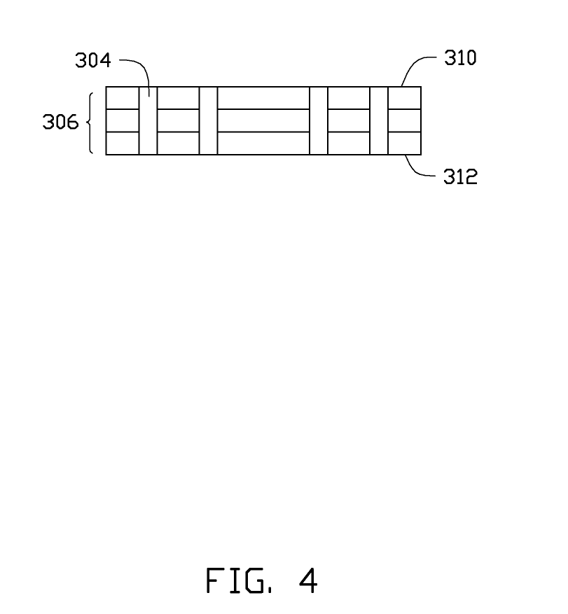

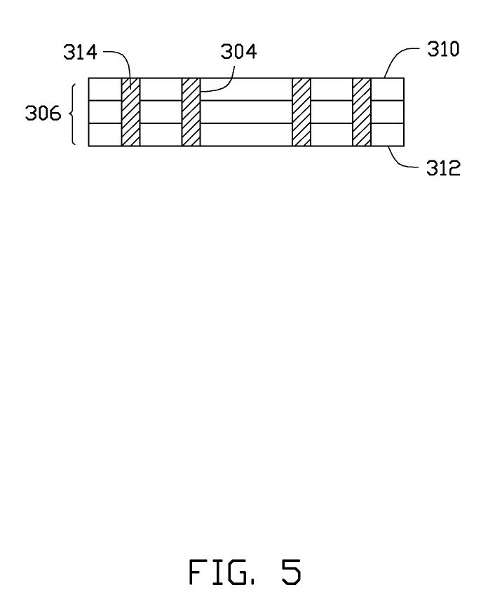

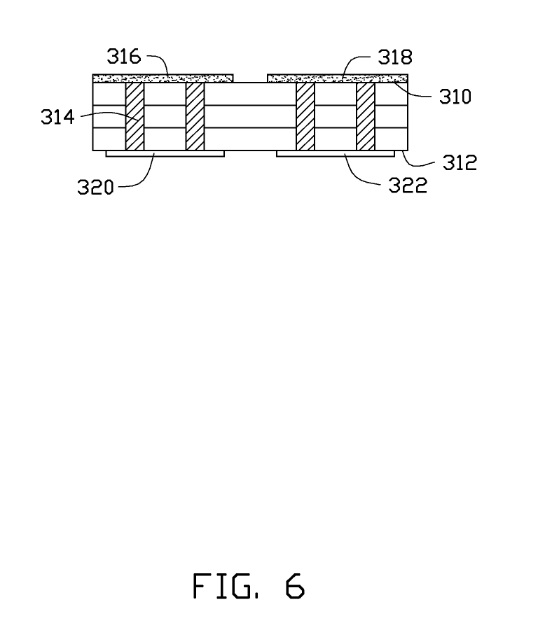

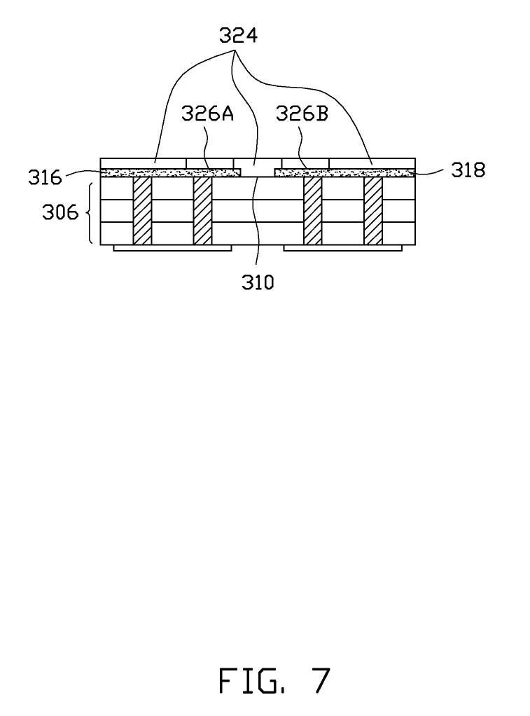

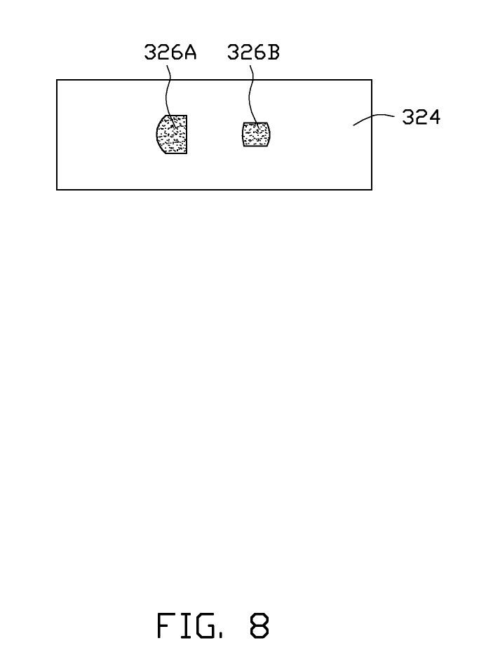

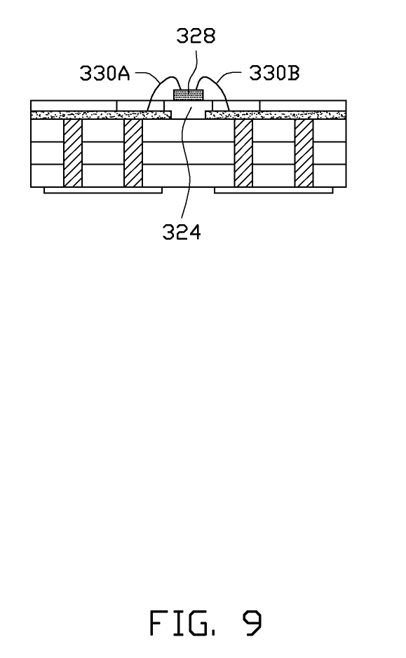

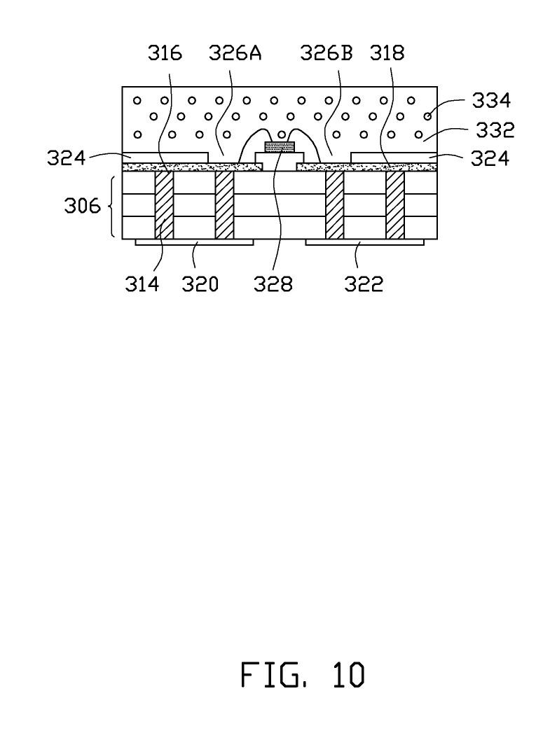

Referring to FIGS. 1-10, a fabrication method for light emitting element package is as follows.

In block S202, a substrate 306 is provided. The substrate 306 includes a plurality of films. The films include ceramic, AlN, Al₂O₃, BN, Si₃N₄ or SiC. The substrate 306 is configured for uniformly conducting the heat generated by light emitting element. The substrate 306 has a first surface 310 (i.e., a top surface) and a bottom surface 312 opposite to the first surface 310.

In block S204, a plurality of through holes 304 is defined in the substrate 306. The through holes 304 can be formed by drill or laser drill.

In block S206, metal is filled in the through holes 304 to form a plurality of metal pins 314. The metal can be Ni, Cr, Au, Ag, Pt, Cu, Zn, Ti, Si, Sn, Al or a combination thereof.

A first conductive layer 316 and a second conductive layer 318 are formed on the first surface 310. The first conductive layer 316 and the second conductive layer 318 are respectively electrically coupled to a number of metal pins 314. The first conductive layer 316 and the second conductive layer 318 are Ag.

A first solder pad 320 and a second solder pad 322 are formed on the bottom surface 312 of the substrate 306. The first conductive layer 316 and the second conductive layer 318 are respectively electrically coupled to the first solder pad 320 and the second solder pad 322 through the metal pins 314.

In block S208, a reflection layer 324 is formed on the first conductive layer 316, the second conductive layer 318 and the first surface 310 of the substrate 306. A part of the first conductive layer 316 and a part of the second conductive layer 318 are not covered by the reflection layer 324 whereby the first conductive layer 316 has a first exposed region 326A and the second conductive layer 318 has a second exposed region 326B.

The reflection layer 324 is configured for reflecting the light from the light emitting element to maximize light utility efficiency and luminescence.

The first solder pad 320, the second solder pad 322 and the substrate 306 are integrally formed through low temperature co-fired process.

The reflection layer 324 includes SiO₂, B₂O₃, MgO or a combination thereof, providing high reflectance. Heat generated by the light emitting element chip is uniformly conducted by the reflection layer 324, and formation of hot spots thereon minimized efficiently.

In block S210, at least one light emitting element 328 is mounted on a center of the reflection layer 324. The heat generated by the at least one light emitting element 328 is efficiently dissipated by the reflection layer 324. The at least one light emitting element 328 is electrically connected to the first and second exposed regions 326A, 326B of the first and second conductive layers 316, 318 via two golden wires 330A, 330B.

In block S212, an encapsulation layer 332 is mounted on the at least one light emitting element 328. The encapsulation layer 332 is epoxy, silicone or a combination thereof. Phosphor elements 334 can be dispersed in the encapsulation layer 332 to modify color of the light from the at least one light emitting element 328. The phosphor elements 334 can be YAG, TAG, silicate, nitride, nitrogen oxide, phosphide, sulfide or a combination thereof. The encapsulation layer 332 is formed by transfer molding, spin coating, or injection molding. The phosphor elements 334 can also be a film or a lumiramic plate, not limited to the shape disclosed. The phosphor elements 334 are formed by coating, paste, or spray. In the embodiment, the phosphor elements 334 are distributed in the encapsulation layer 332.

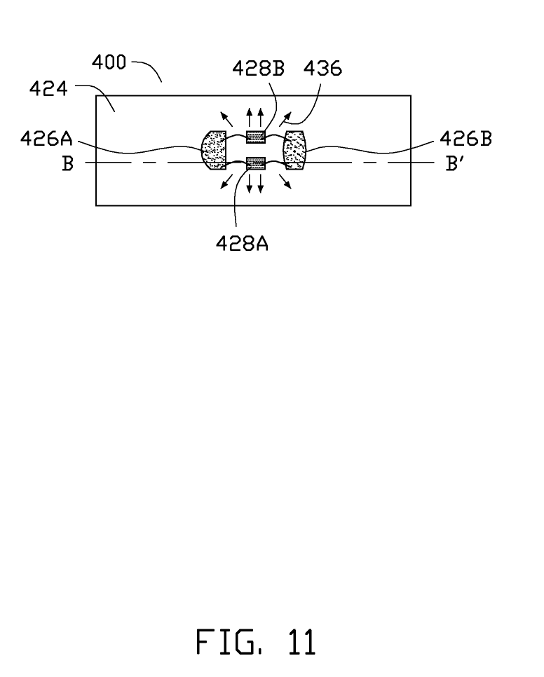

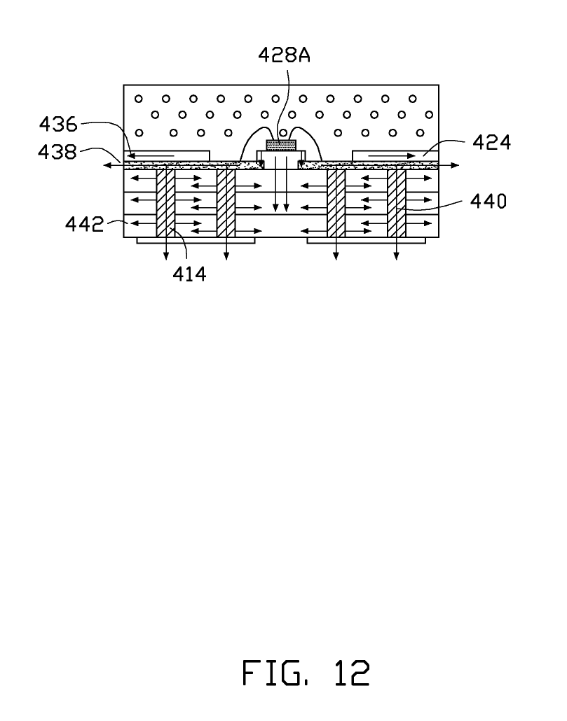

Referring to FIGS. 11-12, the heat generated by a light emitting element package 400 with two light emitting elements 428A, 428B is efficiently dissipated along the arrows 436, 438, 440, 442.

The heat generated by the light emitting element can be efficiently dissipated through the reflection layer 424, the first conductive layer 426A, the second conductive layer 426B and the metal pins 414. The total luminance of the light emitting package 400 increases according to the reflection layer 424.

More than two light emitting elements can be mounted on the light emitting element package 400.

While the disclosure has been described by way of example and in terms of exemplary embodiment, it is to be understood that the disclosure is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A fabrication method for a light emitting element package, the method comprising:
providing a substrate defining a plurality of through holes therein;
forming a plurality of metal pins in the through holes;
forming a reflection layer on a surface of the substrate;
mounting at least one light emitting element on the reflection layer on the substrate, the at least one light emitting element electrically connecting with the metal pins; and
forming an encapsulation layer to encapsulate the light emitting elements.

2. The fabrication method for a light emitting element package of claim 1, further comprising forming a first conductive layer and a second conductive layer between the substrate and the reflection layer, the at least one light emitting element being electrically connected to the metal pins via the first and second conductive layers.

3. The fabrication method for a light emitting element package of claim 2, wherein the first conductive layer and the second conductive layer are made of Ag.

4. The fabrication method for a light emitting element package of claim 2, further comprising forming at least two solder pads on a bottom surface of the substrate, wherein the at least two solder pads are electrically coupled to the first conductive layer and the second conductive layer of the substrate through the metal pins.

5. The fabrication method for a light emitting element package of claim 1, wherein the reflection layer comprises SiO₂, B₂O₃ and MgO.

6. A fabrication method for a light emitting element package, the method comprising:
providing a substrate;
defining a plurality of through holes in the substrate;
forming a plurality of metal pins in the through holes;
forming a reflection layer on a surface of the substrate;
mounting at least one light emitting element on the reflection layer on the substrate, the at least one light emitting element being electrically connected with the metal pins; and
forming an encapsulation layer to encapsulate the light emitting element.

7. The fabrication method for a light emitting element package of claim 6, further comprising:
forming a first conductive layer and a second conductive layer,
wherein the first conductive layer and the second conductive layer are electrically coupled to the metal pins and the at least one light emitting element being electrically connected with the metal pins via the first and second conductive layers.

8. The fabrication method for a light emitting element package of claim 6, wherein the encapsulation layer comprises phosphor elements.

9. The fabrication method for a light emitting element package of claim 6, wherein the reflection layer comprises SiO₂, B₂O₃ and MgO.

10. The fabrication method for a light emitting element package of claim 6, further comprising: forming at least two solder pads on a second surface of the substrate, wherein the at least two solder pads on the second surface are electrically coupled to the metal pins.

11. The fabrication method for a light emitting element package of claim 6, further comprising mounting at least one phosphor layer on the at least one light emitting element.

12. The fabrication method for a light emitting element package of claim 11, wherein the at least one phosphor layer comprises YAG, TAG, silicate, nitride, nitrogen oxide, phosphide, sulfide or a combination thereof.

13. A light emitting element package comprising:
a substrate;
a reflection layer formed on the substrate;
at least one light emitting element mounted on the package substrate;
at least two conductive layers electrically coupled to the at least one light emitting element;
a plurality of metal pins electrically coupled to the at least two conductive layers; and
an encapsulation layer mounted on the substrate for encapsulation the at least one light emitting element.

14. The light emitting element package of claim 13, wherein the substrate comprises a plurality of films.

15. The light emitting element package of claim 13, wherein the reflection layer comprises SiO₂, B₂O₃ and MgO.

16. The light emitting element package of claim 13, further comprising at least two solder pads formed on a bottom surface of the substrate, the at least two solder pads electrically coupled to the metal pins.
